(19) United States
(12) Patent Application Publication
(10) Pub. No.: US 2025/0028010 A1
(43) Pub. Date: Jan. 23, 2025

(54) SYSTEMS AND METHODS FOR ABNORMAL POWER CONNECTION DETECTION

(71) Applicant: Advanced Micro Devices, Inc., Santa Clara, CA (US)

(72) Inventors: ChaiLin Yu, Pudong (CN); YanHe Qi, Pudong (CN); JiJun Shi, Pudong (CN)

(73) Assignee: Advanced Micro Devices, Inc., Santa Clara, CA (US)

(21) Appl. No.: 18/355,011

(22) Filed: Jul. 19, 2023

(51) Int. Cl. G01R 31/66

(52) U.S. Cl. CPC G01R 31/66

(57) ABSTRACT

A computer-implemented method for abnormal power connection detection can include receiving, by at least one processor, a power signal by a power connector and an additional power signal by an additional power connector. The method can additionally include performing, by the at least one processor, one or more measurements of the additional power signal. The method can also include carrying out, by the at least one processor, one or more response procedures based on the one or more measurements. Various other methods, systems, and computer-readable media are also disclosed.

### BACKGROUND

Power requirements for electronic equipment increase with improvements in equipment performance. As a result, the power levels of connectors continuously rise. The contact tightness of the power connector can affect contact impedance, voltage drop, and power loss of the entire current transmission-path. If the contact impedance of the power connector rises too high, a result can be heat generation that, in extreme cases, can cause a hot melting problem of the connector.

### BRIEF DESCRIPTION OF THE DRAWINGS

The accompanying drawings illustrate a number of example embodiments and are a part of the specification. Together with the following description, these drawings demonstrate and explain various principles of the present disclosure.

FIG. 1 is a block diagram of an example system for abnormal power connection detection.

FIG. 2 is a block diagram of an additional example system for abnormal power connection detection.

FIG. 3 is a flow diagram of an example method for abnormal power connection detection.

FIG. 4 is a graphical illustration of example power cable and/or connector configurations for abnormal power connection detection.

FIG. 5 is a schematic block diagram illustrating an example computing device for abnormal power connection detection.

FIG. 6 is a system block diagram illustrating an example computing device for abnormal power connection detection.

FIG. 7 is a flow diagram illustrating example procedures for abnormal power connection detection.

Throughout the drawings, identical reference characters and descriptions indicate similar, but not necessarily identical, elements. While the example embodiments described herein are susceptible to various modifications and alternative forms, specific embodiments have been shown by way of example in the drawings and will be described in detail herein. However, the example embodiments described herein are not intended to be limited to the particular forms disclosed. Rather, the present disclosure covers all modifications, equivalents, and alternatives falling within the scope of the appended claims.

### DETAILED DESCRIPTION OF EXAMPLE IMPLEMENTATIONS

The present disclosure is generally directed to systems and methods for abnormal power connection detection. An extra signal cable line can be added for main power and an additional power pin connector can be added as a signal detection point. In response to determining that the extra power signal is not ready, a first alarm signal can be generated that informs the system control unit, and a second alarm signal can be disabled. Otherwise in response to determining that the extra power signal is ready, a voltage drop detection unit and current detection unit can be enabled. Then a real contacting impedance of the power connector can be checked based on results from those units and a determination can be made that it is over a target reference contacting impedance. In response to this determination, a second alarm signal can be generated that informs a system control unit so it can carry out one or more response procedures, such as controlling system loading (e.g., system throttling, etc.). In some examples, an abnormal alarm unit can be used to inform a user and/or system administrator, a hysteresis control unit can be used to avoid jitter, a low-pass filter unit can be used to avoid mis-touching protection, and a proportion adjustment unit can be used to correct a current sense signal.

The disclosed systems and methods can achieve numerous benefits. For example, overheating or burning of connectors due to abnormal connection can be avoided. These benefits can be realized in high power connectors that reduce contact impedance through a multi pin parallel connection. Bending and poor contacting can cause high resistance in some pins, and more current can transfer to pins having lowest resistance. Resistance variation between pins leads to unbalanced current. High contacting impedance and high current density in some pins cause high temperature. If the temperature rise accumulates and overcomes the specifications of the plastic shell, it can cause a hot melting or burning issue.

In one example, a computing device includes power input circuitry configured to receive a power signal by a power connector and an additional power signal by an additional power connector, power sensing circuitry configured to perform one or more measurements of the additional power signal, and response circuitry configured to carry out one or more response procedures based on the one or more measurements.

Another example can be the previously described example computing device, wherein the one or more response procedures include generating a first alarm signal that informs a system control unit that the additional power signal is not ready and disabling a second alarm signal.

Another example can be any of the previously described example computing devices, wherein the one or more response procedures include enabling a voltage drop detection unit and a current sense unit configured to determine a contacting impedance of the power connector, determining that the contacting impedance of the power connector exceeds a target reference contacting impedance, and generating, in response to the determination, an alarm signal that informs a system control unit that it can carry out one or more additional response procedures.

Another example can be any of the previously described example computing devices, wherein the one or more additional response procedures include at least one of controlling system loading or generating an additional alarm signal that informs at least one of a user or a system administrator.

Another example can be any of the previously described example computing devices, further including one or more hysteresis control units configured to avoid jitter.

Another example can be any of the previously described example computing devices, a low-pass filter configured to avoid mis-touching protection.

Another example can be any of the previously described example computing devices, further including a proportion adjustment unit configured to correct a current sense signal.

In one example, a system can include at least one physical processor and physical memory including computer-executable instructions that, when executed by the at least one physical processor, cause the at least one physical processor to receive a power signal by a power connector and an additional power signal by an additional power connector, perform one or more measurements of the additional power signal, and carry out one or more response procedures based on the one or more measurements.

Another example can be the previously described example system, wherein the one or more response procedures includes generating a first alarm signal that informs a system control unit that the additional power signal is not ready and disabling a second alarm signal.

Another example can be any of the previously described example systems, wherein the one or more response procedures includes enabling a voltage drop detection unit and a current sense unit configured to determine a contacting impedance of the power connector, determining that the contacting impedance of the power connector exceeds a target reference contacting impedance, and generating, in response to the determination, an alarm signal that informs a system control unit that it can carry out one or more additional response procedures.

Another example can be any of the previously described example systems, wherein the one or more additional response procedures include at least one of controlling system loading or generating an additional alarm signal that informs at least one of a user or a system administrator.

Another example can be any of the previously described example systems, wherein the computer-executable instructions further cause the at least one physical processor to employ one or more hysteresis control units to avoid jitter.

Another example can be any of the previously described example systems, wherein the computer-executable instructions further cause the at least one physical processor to employ a low-pass filter to avoid mis-touching protection.

Another example can be any of the previously described example systems, wherein the computer-executable instructions further cause the at least one physical processor to employ a proportion adjustment unit to correct a current sense signal.

In one example, a computer-implemented method can include receiving, by at least one processor, a power signal by a power connector and an additional power signal by an additional power connector, performing, by the at least one processor, one or more measurements of the additional power signal, and carrying out, by the at least one processor, one or more response procedures based on the one or more measurements.

Another example can be the previously described example method, wherein the one or more response procedures include generating, by the at least one processor, a first alarm signal that informs a system control unit that the additional power signal is not ready, and disabling, by the at least one processor, a second alarm signal.

Another example can be any of the previously described example methods, wherein the one or more response procedures includes enabling, by the at least one processor, a voltage drop detection unit and a current sense unit configured to determine a contacting impedance of the power connector, determining, by the at least one processor, that the contacting impedance of the power connector exceeds a target reference contacting impedance; and generating, by the at least one processor and in response to the determination, an alarm signal that informs a system control unit that it can carry out one or more additional response procedures.

Another example can be any of the previously described example methods, wherein the one or more additional response procedures include at least one of controlling, by the at least one processor, system loading or generating, by the at least one processor, an additional alarm signal that informs at least one of a user or a system administrator.

Another example can be any of the previously described example methods, further including employing, by the at least one processor, one or more hysteresis control units to avoid jitter.

Another example can be any of the previously described example methods, further including employing, by the at least one processor, a low-pass filter to avoid mis-touching protection.

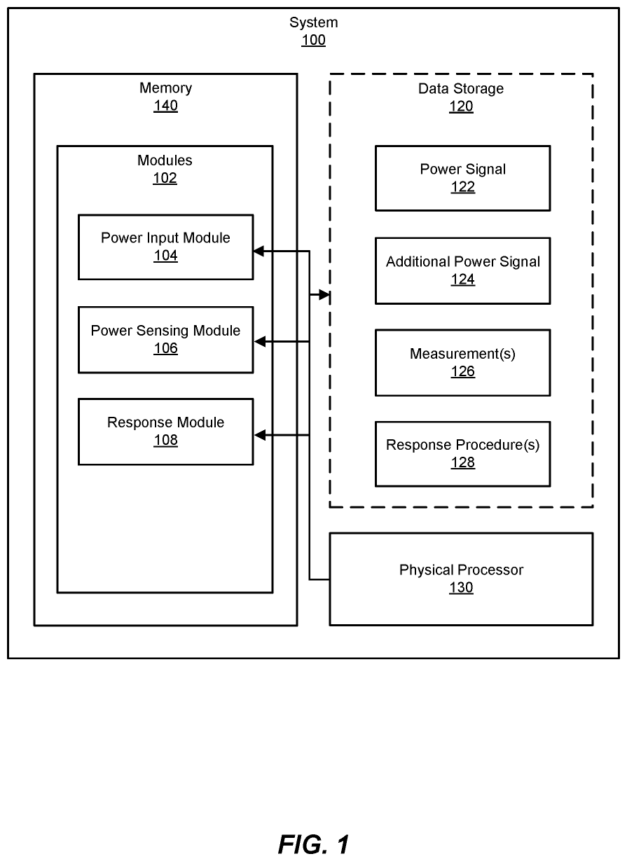

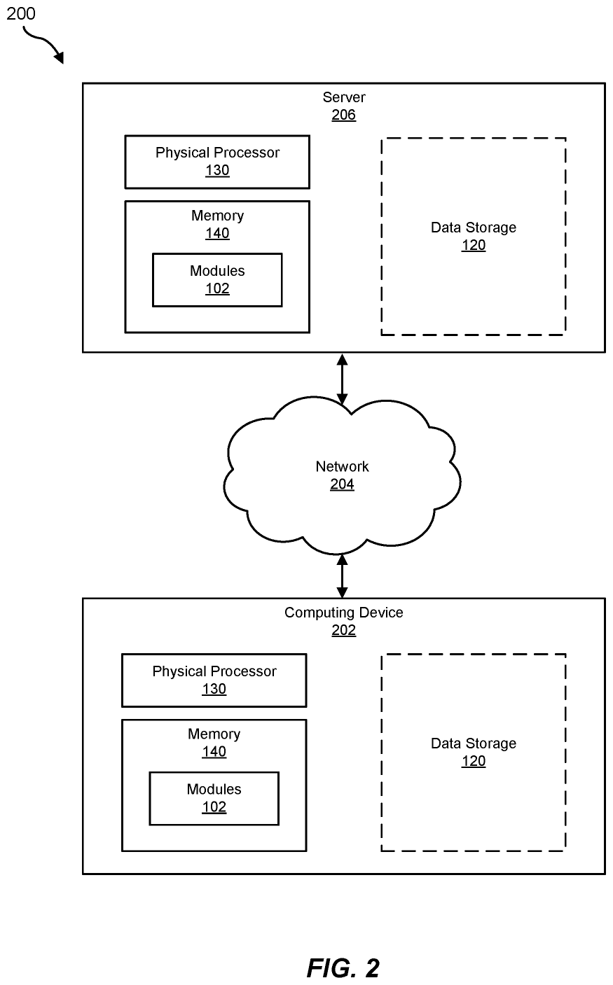

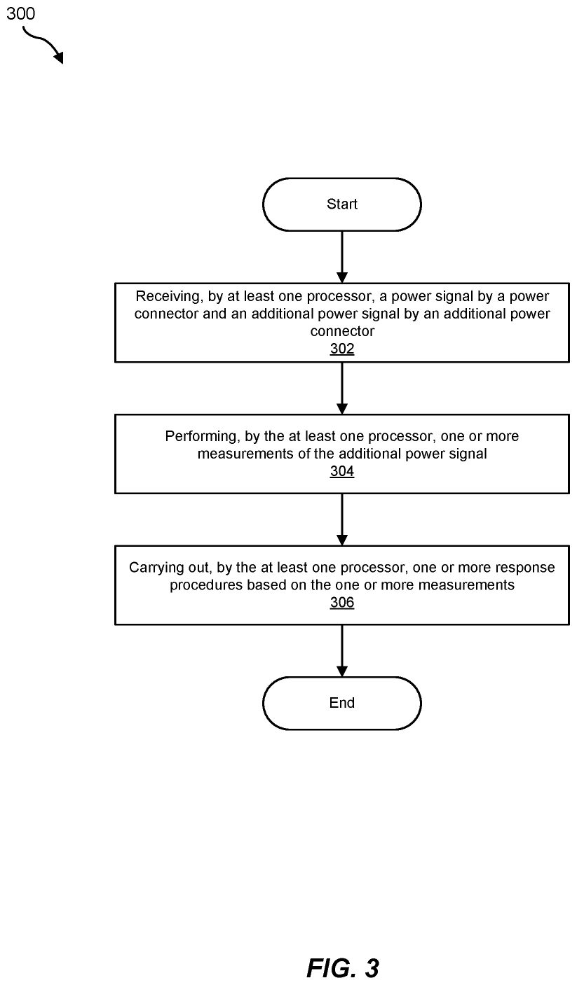

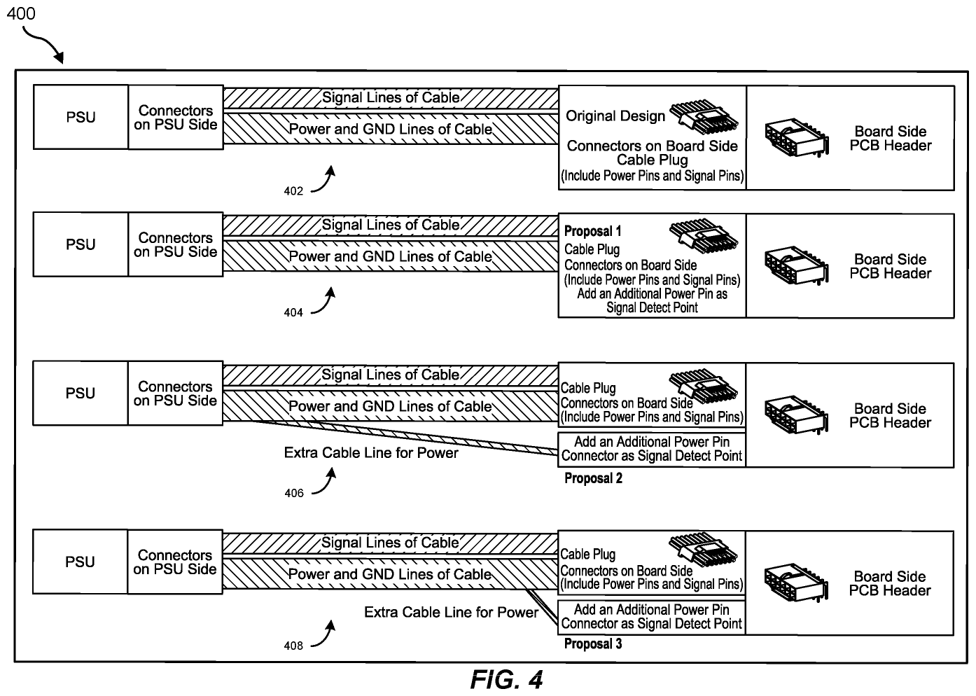

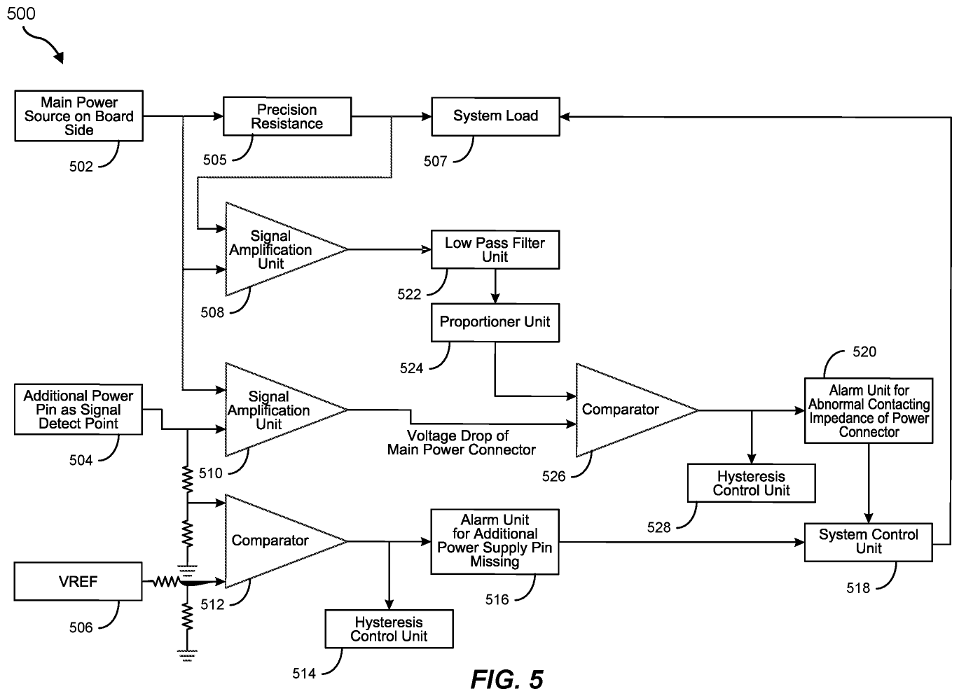

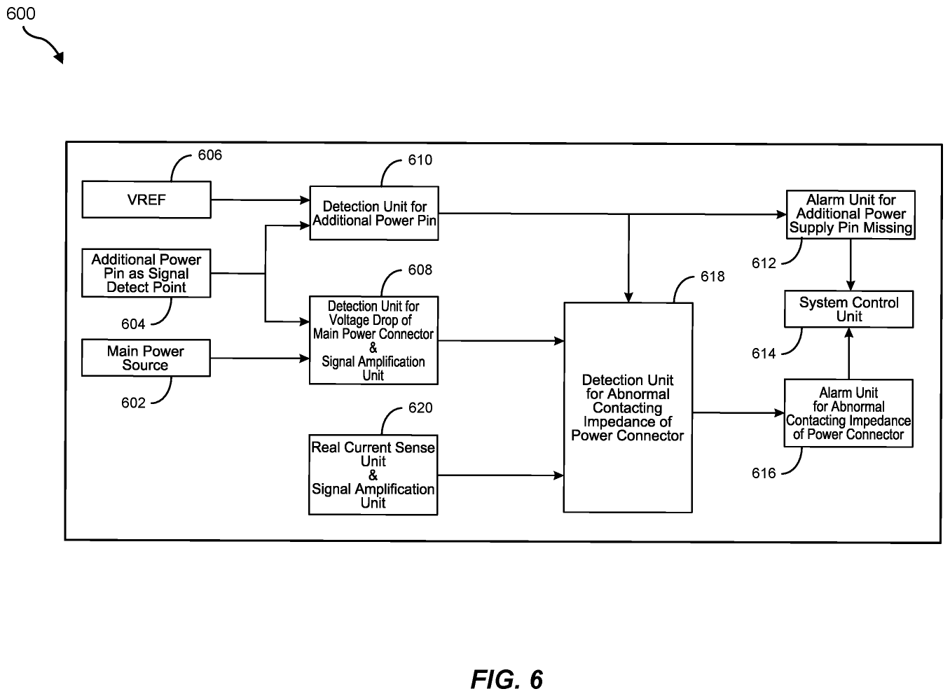

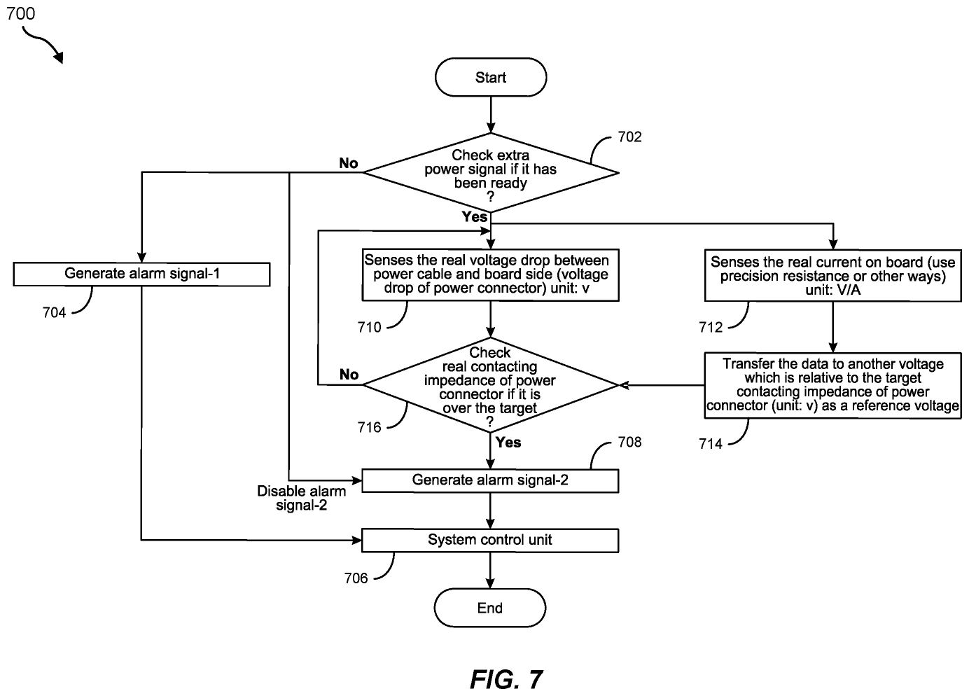

The following will provide, with reference to FIGS. 1-2, detailed descriptions of example systems for abnormal power connection detection. Detailed descriptions of corresponding computer-implemented methods will also be provided in connection with FIG. 3. In addition, detailed descriptions of example power cable and/or connector configurations for abnormal power connection detection will be provided in connection with FIG. 4. Further, detailed descriptions of example computing devices for abnormal power connection detection will be provided in connection with FIGS. 5 and 6. Finally, detailed descriptions of example procedures for abnormal power connection detection will be provided in connection with FIG. 7.

FIG. 1 is a block diagram of an example system 100 for abnormal power connection detection. As illustrated in this figure, example system 100 can include one or more modules 102 for performing one or more tasks. As will be explained in greater detail below, modules 102 can include a power input module 104, a power sensing module 106, and a response module 108. Although illustrated as separate elements, one or more of modules 102 in FIG. 1 can represent portions of a single module or application.

In certain implementations, one or more of modules 102 in FIG. 1 can represent one or more software applications or programs that, when executed by a computing device, can cause the computing device to perform one or more tasks. For example, and as will be described in greater detail below, one or more of modules 102 can represent modules stored and configured to run on one or more computing devices, such as the devices illustrated in FIG. 2 (e.g., computing device 202 and/or server 206). One or more of modules 102 in FIG. 1 can also represent all or portions of one or more special-purpose computers configured to perform one or more tasks.

The term “modules,” as used herein, can generally refer to one or more functional components of a computing device. For example, and without limitation, a module or modules can correspond to hardware, software, or combinations thereof. In turn, hardware can correspond to analog circuitry, digital circuitry, communication media, or combinations thereof. In some implementations, the modules can be implemented as microcode (e.g., digital and/or analog circuitry) and/or one or more firmware in a graphics processing unit.

As illustrated in FIG. 1, example system 100 can also include one or more memory devices, such as memory 140. Memory 140 generally represents any type or form of volatile or non-volatile storage device or medium capable of storing data and/or computer-readable instructions. In one example, memory 140 can store, load, and/or maintain one or more of modules 102. Examples of memory 140 include, without limitation, Random Access Memory (RAM), Read Only Memory (ROM), flash memory, Hard Disk Drives (HDDs), Solid-State Drives (SSDs), optical disk drives, caches, variations or combinations of one or more of the same, or any other suitable storage memory.

As illustrated in FIG. 1, example system 100 can also include one or more physical processors, such as physical processor 130. Physical processor 130 generally represents any type or form of hardware-implemented processing unit capable of interpreting and/or executing computer-readable instructions. In one example, physical processor 130 can access and/or modify one or more of modules 102 stored in memory 140. Additionally or alternatively, physical processor 130 can execute one or more of modules 102 to facilitate abnormal power connection detection. Examples of physical processor 130 include, without limitation, microprocessors, microcontrollers, Central Processing Units (CPUs), Field-Programmable Gate Arrays (FPGAs) that implement softcore processors, Application-Specific Integrated Circuits (ASICs), portions of one or more of the same, variations or combinations of one or more of the same, or any other suitable physical processor.

As illustrated in FIG. 1, example system 100 can also include one or more instances of stored data, such as data storage 120. Data storage 120 generally represents any type or form of stored data, however stored (e.g., signal line transmissions, capacitors, bit registers, flip flops, software in rewritable memory, configurable hardware states, combinations thereof, etc.). In one example, data storage 120 includes databases, spreadsheets, tables, lists, matrices, trees, or any other type of data structure. Examples of data storage 120 include, without limitation, power signal 122, additional power signal 124, measurement(s) 126, and response procedure(s) 128.

Example system 100 in FIG. 1 can be implemented in a variety of ways. For example, all or a portion of example system 100 can represent portions of example system 200 in FIG. 2. As shown in FIG. 2, system 200 can include a computing device 202 in communication with a server 206 via a network 204. In one example, all or a portion of the functionality of modules 102 can be performed by computing device 202, server 206, and/or any other suitable computing system. As will be described in greater detail below, one or more of modules 102 from FIG. 1 can, when executed by at least one processor of computing device 202 and/or server 206, enable computing device 202 and/or server 206 to perform abnormal power connection detection.

Computing device 202 generally represents any type or form of computing device capable of reading computer-executable instructions. In some implementations, computing device 202 can be and/or include one or more graphics processing units having a chiplet processor connected by a switch fabric. Additional examples of computing device 202 include, without limitation, laptops, tablets, desktops, servers, cellular phones, Personal Digital Assistants (PDAs), multimedia players, embedded systems, wearable devices (e.g., smart watches, smart glasses, etc.), smart vehicles, so-called Internet-of-Things devices (e.g., smart appliances, etc.), gaming consoles, variations or combinations of one or more of the same, or any other suitable computing device.

Server 206 generally represents any type or form of computing device that is capable of reading computer-executable instructions. In some implementations, computing device 202 can be and/or include a cloud service (e.g., cloud gaming server) that includes one or more graphics processing units having a chiplet processor connected by a switch fabric. Additional examples of server 206 include, without limitation, storage servers, database servers, application servers, and/or web servers configured to run certain software applications and/or provide various storage, database, and/or web services. Although illustrated as a single entity in FIG. 2, server 206 can include and/or represent a plurality of servers that work and/or operate in conjunction with one another.

Network 204 generally represents any medium or architecture capable of facilitating communication or data transfer. In one example, network 204 can facilitate communication between computing device 202 and server 206. In this example, network 204 can facilitate communication or data transfer using wireless and/or wired connections. Examples of network 204 include, without limitation, an intranet, a Wide Area Network (WAN), a Local Area Network (LAN), a Personal Area Network (PAN), the Internet, Power Line Communications (PLC), a cellular network (e.g., a Global System for Mobile Communications (GSM) network), portions of one or more of the same, variations or combinations of one or more of the same, or any other suitable network.

Many other devices or subsystems can be connected to system 100 in FIG. 1 and/or system 200 in FIG. 2. Conversely, all of the components and devices illustrated in FIGS. 1 and 2 need not be present to practice the implementations described and/or illustrated herein. The devices and subsystems referenced above can also be interconnected in different ways from that shown in FIG. 2. Systems 100 and 200 can also employ any number of software, firmware, and/or hardware configurations. For example, one or more of the example implementations disclosed herein can be encoded as a computer program (also referred to as computer software, software applications, computer-readable instructions, and/or computer control logic) on a computer-readable medium.

The term “computer-readable medium,” as used herein, generally refers to any form of device, carrier, or medium capable of storing or carrying computer-readable instructions. Examples of computer-readable media include, without limitation, transmission-type media, such as carrier waves, and non-transitory-type media, such as magnetic-storage media (e.g., hard disk drives, tape drives, and floppy disks), optical-storage media (e.g., Compact Disks (CDs), Digital Video Disks (DVDs), and BLU-RAY disks), electronic-storage media (e.g., solid-state drives and flash media), and other distribution systems.

FIG. 3 is a flow diagram of an example computer-implemented method 300 for abnormal power connection detection. The steps shown in FIG. 3 can be performed by any suitable computer-executable code and/or computing system, including system 100 in FIG. 1, system 200 in FIG. 2, and/or variations or combinations of one or more of the same. In one example, each of the steps shown in FIG. 3 can represent an algorithm whose structure includes and/or is represented by multiple sub-steps, examples of which will be provided in greater detail below.

The term “computer-implemented method,” as used herein, can generally refer to a method performed by hardware or a combination of hardware and software. For example, hardware can correspond to analog circuitry, digital circuitry, communication media, or combinations thereof. In some implementations, hardware can correspond to digital and/or analog circuitry arranged to carry out one or more portions of the computer-implemented method. In some implementations, hardware can correspond to physical processor 130 of FIG. 1. Additionally, software can correspond to software applications or programs that, when executed by the hardware, can cause the hardware to perform one or more tasks that carry out one or more portions of the computer-implemented method. In some implementations, software can correspond to one or more of modules 102 stored in memory 140 of FIG. 1.

As illustrated in FIG. 3, at step 302 one or more of the systems described herein can receive a power signal. For example, power input module 104 can, as part of computing device 202 in FIG. 2, receive, by at least one processor, a power signal by a power connector and an additional power signal by an additional power connector.

The term “power signal,” as used herein, can generally refer to a signal having a finite average power. For example, and without limitation, a power signal can supply a voltage and current required by a load.

The term “power connector,” as used herein, can generally refer to device that provides power to another device. For example, and without limitation, a power connector can allow an electrical current to pass through it for the exclusive purpose of providing power to a device (e.g., not a data stream).

The systems described herein can perform step 302 in a variety of ways. In one example, power input module 104 can, as part of computing device 202 in FIG. 2, receive the power signal and the additional power signal using two or more power connector elements (e.g., pins, sockets, etc.) of same or different power connectors. In some of these implementations, separate power connectors can be connected to separate power cables. In others of these implementations, a same power connector can have pins that provide separate power input signals from provided by a connection to an individual power cable. Additionally, power input module 104 can, as part of computing device 202 in FIG. 2, route the power signal and/or the additional power signal to one or more detection units, such as a detection unit for voltage drop of the power signal and/or a detection unit for the additional power connector. In some of these implementations, the power input module 104 can, as part of computing device 202 in FIG. 2, route the power signal and/or the additional power signal to one or more amplifiers, resistors, and/or comparators.

At step 304 one or more of the systems described herein can perform a measurement. For example, power sensing module 106 can, as part of computing device 202 in FIG. 2, perform, by the at least one processor, one or more measurements of the additional power signal.

The term “measurement,” as used herein, can generally refer to the process of associating numbers with physical quantities and phenomena. For example, a measurement can be a sensed or determined voltage, current, etc.

The systems described herein can perform step 304 in a variety of ways. In one example, power sensing module 106 can, as part of computing device 202 in FIG. 2, measure presence or absence of the additional power signal. Additionally or alternatively, power sensing module 106 can, as part of computing device 202 in FIG. 2, measure voltage drop of the power signal. Additionally, power sensing module 106 can, as part of computing device 202 in FIG. 2, employ, by the at least one processor, one or more hysteresis control units to avoid jitter. Alternatively or additionally, power sensing module 106 can, as part of computing device 202 in FIG. 2, employ, by the at least one processor, a low-pass filter to avoid mis-touching protection.

At step 306 one or more of the systems described herein can respond to the measurement. For example, response module 108 can, as part of computing device 202 in FIG. 2, carry out, by the at least one processor, one or more response procedures based on the one or more measurements.

The systems described herein can perform step 306 in a variety of ways. In one example, response module 108 can, as part of computing device 202 in FIG. 2, generate, by the at least one processor, a first alarm signal that informs a system control unit that the additional power signal is not ready, and disable, by the at least one processor, a second alarm signal. Alternatively or additionally, response module 108 can, as part of computing device 202 in FIG. 2, enable, by the at least one processor, a voltage drop detection unit and a current sense unit configured to determine a contacting impedance of the power connector, determine, by the at least one processor, that the contacting impedance of the power connector exceeds a target reference contacting impedance, and generate, by the at least one processor and in response to the determination, an alarm signal that informs a system control unit that it can carry out one or more additional response procedures. In some of these implementations, response module 108 can, as part of computing device 202 in FIG. 2, control, by the at least one processor, system loading (e.g., system throttling) and/or generate, by the at least one processor, an additional alarm signal that informs a user and/or a system administrator.

FIG. 4 illustrates example power cable and/or connector configurations 400 for abnormal power connection detection. For example, configuration 402 corresponds to an original design having a connector that receives signal lines and power and grounds lines of an individual power cable. In contrast to configuration 402, configurations 404, 406, and 408 have additional power connection elements that facilitate abnormal power connection detection. Configuration 404, for example, has the individual power cable configured with a cable plug connector on a board side of the power cable that has an additional power pin as a signal detection point. Additionally, configuration 406 has an additional cable line for power and an additional power pin connector on a board side of the power cable as a signal detection point. The additional cable line for power can originate at and extend from power connectors on a power supply unit side of the power cable. The additional power pin of configuration 406 can be implemented as part of the cable plug connector on the board side of the power cable or can be implemented using a separate cable plug connector on the board side of the power cable. Like configuration 406, configuration 408 has an additional cable line for power and an additional power pin connector on a board side of the power cable as a signal detection point. Likewise, the additional power pin of configuration 408 can be implemented as part of the cable plug connector on the board side of the power cable or can be implemented using a separate cable plug connector on the board side of the power cable. However, the additional cable line for power can originate at and extend from a position proximate to cable plug connector on the board side of the power cable. With configurations 404, 406, and/or 408, a board of a computing device can receive a power signal by a power connector and an additional power signal by an additional power connector.

FIG. 5 illustrates an example computing device 500 for abnormal power connection detection. For example, main power source 502 of the computing device 500 can receive a main power signal. Additionally, additional power pin 504 of the computing device 500 can receive an additional power signal as a signal detection point. Further a reference voltage 506 can be provided by computing device 500.

Main power source 502 of the computing device 500 can route main power to a precision resistance element 505 (e.g., e-fuse, etc.) and thereafter to a system load 507 and a signal amplification unit 508 (e.g., transistor, etc.). Main power source 502 of the computing device 500 can route main power to the signal amplification unit 508 and an additional signal amplification unit 510 (e.g., transistor, etc.). Additional power pin 504 of the computing device can route the additional power signal to the additional signal amplification unit 510 and to a comparator 512 to which computing device 500 also supplies the reference voltage 506.

Computing device 500 can implement a hysteresis control unit 514 on an output of comparator 512 to avoid jitter. Additionally, an alarm unit 516 for the additional power supply pin 504 can receive the resulting output from comparator 512. Alarm unit 516 can be configured to determine that the additional power signal is not ready and, in response to determination, generate a first alarm signal that informs a system control unit 518 that the additional power signal is not ready.

In response to the first alarm signal, system control unit 518 can carry out one or more response procedures. For example, system control unit can disable a second alarm signal form an additional alarm unit 520 for abnormal contacting impedance of a power connector of main power source 502. In some implementation, system control unit 518 can disable the second alarm signal by ignoring the second alarm signal received from additional alarm unit 520. Alternatively or additionally, system control unit 518 can respond to the first alarm signal by generating an additional alarm signal that informs a user and/or a system administrator that the additional power signal is not ready.

Signal amplification unit 508 can provide an amplified signal output to a low pass filter unit 522, and thereafter to a proportioner unit 524. In some implementations, computing device 500 can implement low pass filter unit 522 to avoid mistouching protection. Alternatively or additionally, computing device 500 can implement proportioner unit 524 to correct a sensed current signal.

Comparator 526 can receive the signal output by the proportioner unit 524. Comparator 526 can also receive an additional signal from signal amplification unit 510. This additional signal can correspond to a voltage drop of the power connector of main power source 502. Computing device 500 can implement comparator 526 to detect abnormal contacting impedance of the power connector of main power source 502 and generate a signal indicating the same to additional alarm unit 520. Computing device 500 can also implement a hysteresis control unit 528 on an output of comparator 526 to avoid jitter.

Additional alarm unit 520 can generate an alarm in response to detection of the abnormal contacting impedance of the power connector of main power source 502. System control unit 518 can receive this alarm and respond accordingly. For example, system control unit 518 can control system loading (e.g., system throttling) and/or generate an additional alarm signal that informs a user and/or a system administrator of detection of the abnormal contacting impedance of the power connector of main power source 502.

FIG. 6 illustrates an example computing device 600 for abnormal power connection detection. For example, main power source 602 of the computing device 600 can receive a main power signal. Additionally, additional power pin 604 of the computing device 600 can receive an additional power signal as a signal detection point. Further a reference voltage 606 can be provided by computing device 600.

Main power source 602 of the computing device 600 can route main power to a voltage drop detection and signal amplification unit 608. Additional power pin 604 of the computing device can route the additional power signal to the voltage drop detection and signal amplification unit 608 and to a detection unit 610 for the additional power pin 604, to which computing device 600 can also supply the reference voltage 606.

An alarm unit 612 for the additional power supply pin 604 can receive an output signal from detection unit 610 for the additional power pin 604. Detection unit 610 for the additional power pin 604 can be configured to determine that the additional power signal is not ready and, in response to determination, trigger generation of a first alarm signal by alarm unit 612 that informs a system control unit 614 that the additional power signal is not ready.

In response to the first alarm signal, system control unit 614 can carry out one or more response procedures. For example, system control unit 614 can disable a second alarm signal from an additional alarm unit 616 for abnormal contacting impedance of a power connector of main power source 602. In some implementation, system control unit 614 can disable the second alarm signal by ignoring the second alarm signal received from additional alarm unit 616. Alternatively or additionally, system control unit 614 can respond to the first alarm signal by generating an additional alarm signal that informs a user and/or a system administrator that the additional power signal is not ready.

Voltage drop detection and signal amplification unit 608 can provide an amplified signal output to a detection unit 618 for abnormal contacting impedance of a connector of main power source 602. Detection unit 618 can also receive the output signal from detection unit 610 for the additional power pin 604 and an output signal from a real current sense and signal amplification unit 620. Detection unit 618 can detect abnormal contacting impedance of the power connector of main power source 602 and generate a signal indicating the same to additional alarm unit 616.

Additional alarm unit 616 can generate an alarm in response to detection of the abnormal contacting impedance of the power connector of main power source 602. System control unit 614 can receive this alarm and respond accordingly. For example, system control unit 614 can control system loading (e.g., system throttling) and/or generate an additional alarm signal that informs a user and/or a system administrator of detection of the abnormal contacting impedance of the power connector of main power source 602.

FIG. 7 illustrates example procedures 700 for abnormal power connection detection. For example, the procedure can begin by checking whether an additional power signal is ready at decision step 702. If not, then processing may proceed to step 704 at which the process can generate a first alarm signal that informs a system control unit 706 that the additional power signal is not ready. Additionally, generation of a second alarm signal at step 708 can be disabled in response to the determination, at decision step 702, that the additional power signal is not ready.

If it is determined, at decision step 702, that the additional power signal is ready, then processing can proceed to steps 710 and 712. At step 710, the process can sense (e.g., in volts, etc.) a real voltage drop between a power cable and a board side power connector. At step 712, the process can sense the real current on board using, for example, precision resistance, etc. Processing can proceed from step 712 to step 714, at which the process can transfer e.g., convert, transform, etc.) the sensed current data to another voltage (e.g., reference voltage, etc.) that is relevant to the target contacting impedance of the power connector. Processing can proceed from steps 716 and 714 to decision step 716.

At decision step 716, the process can check if a real contacting impedance of the power connector is higher than the target contacting impedance. If so, processing can proceed to step 708, in which an alarm signal can be generated that causes system control unit 706 to control system loading (e.g., system throttling) and/or generate an additional alarm signal that informs a user and/or a system administrator.

As set forth above, the disclosed systems and methods can perform abnormal power connection detection. For example, an extra signal cable line can be added for main power and an additional power pin connector can be added as a signal detection point. In response to determining that the extra power signal is not ready, a first alarm signal can be generated that informs the system control unit, and a second alarm signal can be disabled. Otherwise in response to determining that the extra power signal is ready, a voltage drop detection unit and current detection unit can be enabled. Then a real contacting impedance of the power connector can be checked based on results from those units and a determination can be made that it is over a target reference contacting impedance. In response to this determination, a second alarm signal can be generated that informs a system control unit so it can carry out one or more response procedures, such as controlling system loading (e.g., system throttling, etc.). In some examples, an abnormal alarm unit can be used to inform a user and/or system administrator, a hysteresis control unit can be used to avoid jitter, a low-pass filter unit can be used to avoid mis-touching protection, and a proportion adjustment unit can be used to correct a current sense signal.

The disclosed systems and methods can achieve numerous benefits. For example, overheating or burning of connectors due to abnormal connection can be avoided. These benefits can be realized in high power connectors that reduce contact impedance through a multi pin parallel connection. Bending and poor contacting can cause high resistance in some pins, and more current can transfer to pins having lowest resistance. Resistance variation between pins leads to unbalanced current. High contacting impedance and high current density in some pins cause high temperature. If the temperature rise accumulates and overcomes the specifications of the plastic shell, it can cause a hot melting or burning issue.

While the foregoing disclosure sets forth various implementations using specific block diagrams, flowcharts, and examples, each block diagram component, flowchart step, operation, and/or component described and/or illustrated herein can be implemented, individually and/or collectively, using a wide range of hardware, software, or firmware (or any combination thereof) configurations. In addition, any disclosure of components contained within other components should be considered example in nature since many other architectures can be implemented to achieve the same functionality.

In some examples, all or a portion of example system 100 in FIG. 1 can represent portions of a cloud-computing or network-based environment. Cloud-computing environments can provide various services and applications via the Internet. These cloud-based services (e.g., software as a service, platform as a service, infrastructure as a service, etc.) can be accessible through a web browser or other remote interface. Various functions described herein can be provided through a remote desktop environment or any other cloud-based computing environment.

In various implementations, all or a portion of example system 100 in FIG. 1 can facilitate multi-tenancy within a cloud-based computing environment. In other words, the modules described herein can configure a computing system (e.g., a server) to facilitate multi-tenancy for one or more of the functions described herein. For example, one or more of the modules described herein can program a server to enable two or more clients (e.g., customers) to share an application that is running on the server. A server programmed in this manner can share an application, operating system, processing system, and/or storage system among multiple customers (i.e., tenants). One or more of the modules described herein can also partition data and/or configuration information of a multi-tenant application for each customer such that one customer cannot access data and/or configuration information of another customer.

According to various implementations, all or a portion of example system 100 in FIG. 1 can be implemented within a virtual environment. For example, the modules and/or data described herein can reside and/or execute within a virtual machine. As used herein, the term “virtual machine” generally refers to any operating system environment that is abstracted from computing hardware by a virtual machine manager (e.g., a hypervisor).

In some examples, all or a portion of example system 100 in FIG. 1 can represent portions of a mobile computing environment. Mobile computing environments can be implemented by a wide range of mobile computing devices, including mobile phones, tablet computers, e-book readers, personal digital assistants, wearable computing devices (e.g., computing devices with a head-mounted display, smartwatches, etc.), variations or combinations of one or more of the same, or any other suitable mobile computing devices. In some examples, mobile computing environments can have one or more distinct features, including, for example, reliance on battery power, presenting only one foreground application at any given time, remote management features, touchscreen features, location and movement data (e.g., provided by Global Positioning Systems, gyroscopes, accelerometers, etc.), restricted platforms that restrict modifications to system-level configurations and/or that limit the ability of third-party software to inspect the behavior of other applications, controls to restrict the installation of applications (e.g., to only originate from approved application stores), etc. Various functions described herein can be provided for a mobile computing environment and/or can interact with a mobile computing environment.

The process parameters and sequence of steps described and/or illustrated herein are given by way of example only and can be varied as desired. For example, while the steps illustrated and/or described herein can be shown or discussed in a particular order, these steps do not necessarily need to be performed in the order illustrated or discussed. The various example methods described and/or illustrated herein can also omit one or more of the steps described or illustrated herein or include additional steps in addition to those disclosed.

While various implementations have been described and/or illustrated herein in the context of fully functional computing systems, one or more of these example implementations can be distributed as a program product in a variety of forms, regardless of the particular type of computer-readable media used to actually carry out the distribution. The implementations disclosed herein can also be implemented using modules that perform certain tasks. These modules can include script, batch, or other executable files that can be stored on a computer-readable storage medium or in a computing system. In some implementations, these modules can configure a computing system to perform one or more of the example implementations disclosed herein.

The preceding description has been provided to enable others skilled in the art to best utilize various aspects of the example implementations disclosed herein. This example description is not intended to be exhaustive or to be limited to any precise form disclosed. Many modifications and variations are possible without departing from the spirit and scope of the present disclosure. The implementations disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. A computing device, comprising:
power input circuitry configured to receive a power signal by a power connector and an additional power signal by an additional power connector;
power sensing circuitry configured to perform one or more measurements of the additional power signal; and
response circuitry configured to carry out one or more response procedures based on the one or more measurements.

2. The computing device of claim 1, wherein the one or more response procedures include:
generating a first alarm signal that informs a system control unit that the additional power signal is not ready; and
disabling a second alarm signal.

3. The computing device of claim 1, wherein the one or more response procedures include:
enabling a voltage drop detection unit and a current sense unit configured to determine a contacting impedance of the power connector;
determining that the contacting impedance of the power connector exceeds a target reference contacting impedance; and
generating, in response to the determination, an alarm signal that informs a system control unit that it can carry out one or more additional response procedures.

4. The computing device of claim 3, wherein the one or more additional response procedures include at least one of:
controlling system loading; or
generating an additional alarm signal that informs at least one of a user or a system administrator.

5. The computing device of claim 1, further comprising:
one or more hysteresis control units configured to avoid jitter.

6. The computing device of claim 1, further comprising:
a low-pass filter configured to avoid mis-touching protection.

7. The computing device of claim 1, further comprising:
a proportion adjustment unit configured to correct a current sense signal.

8. A system comprising:
at least one physical processor; and
physical memory comprising computer-executable instructions that, when executed by the at least one physical processor, cause the at least one physical processor to:
receive a power signal by a power connector and an additional power signal by an additional power connector;
perform one or more measurements of the additional power signal; and
carry out one or more response procedures based on the one or more measurements.

9. The system of claim 8, wherein the one or more response procedures includes:
generating a first alarm signal that informs a system control unit that the additional power signal is not ready; and
disabling a second alarm signal.

10. The system of claim 8, wherein the one or more response procedures includes:
enabling a voltage drop detection unit and a current sense unit configured to determine a contacting impedance of the power connector;
determining that the contacting impedance of the power connector exceeds a target reference contacting impedance; and
generating, in response to the determination, an alarm signal that informs a system control unit that it can carry out one or more additional response procedures.

11. The system of claim 10, wherein the one or more additional response procedures include at least one of:
controlling system loading; or
generating an additional alarm signal that informs at least one of a user or a system administrator.

12. The system of claim 8, wherein the computer-executable instructions further cause the at least one physical processor to:
employ one or more hysteresis control units to avoid jitter.

13. The system of claim 8, wherein the computer-executable instructions further cause the at least one physical processor to:
employ a low-pass filter to avoid mis-touching protection.

14. The system of claim 8, wherein the computer-executable instructions further cause the at least one physical processor to:
employ a proportion adjustment unit to correct a current sense signal.

15. A computer-implemented method comprising:
receiving, by at least one processor, a power signal by a power connector and an additional power signal by an additional power connector;
performing, by the at least one processor, one or more measurements of the additional power signal; and
carrying out, by the at least one processor, one or more response procedures based on the one or more measurements.

16. The computer-implemented method of claim 15, wherein the one or more response procedures include:
generating, by the at least one processor, a first alarm signal that informs a system control unit that the additional power signal is not ready; and
disabling, by the at least one processor, a second alarm signal.

17. The computer-implemented method of claim 15, wherein the one or more response procedures includes:
enabling, by the at least one processor, a voltage drop detection unit and a current sense unit configured to determine a contacting impedance of the power connector;
determining, by the at least one processor, that the contacting impedance of the power connector exceeds a target reference contacting impedance; and
generating, by the at least one processor and in response to the determination, an alarm signal that informs a system control unit that it can carry out one or more additional response procedures.

18. The computer-implemented method of claim 17, wherein the one or more additional response procedures include at least one of:
controlling, by the at least one processor, system loading; or
generating, by the at least one processor, an additional alarm signal that informs at least one of a user or a system administrator.

19. The computer-implemented method of claim 15, further comprising:
employing, by the at least one processor, one or more hysteresis control units to avoid jitter.

20. The computer-implemented method of claim 15, further comprising:
employing, by the at least one processor, a low-pass filter to avoid mis-touching protection.
